(19) United States
(12) Patent Application Publication
(10) Pub. No.: US 2009/0126589 A1
(43) Pub. Date: May 21, 2009

(54) PATTERNING PROCESS

(76) Inventors: Ian Andrew Maxwell, New South Wales (AU); James Stanislaus Williams, Australian Capital Territory (AU); Jodie Elizabeth Bradby, Australian Capital Territory (AU)

Correspondence Address: KNOBBE MARTENS OLSON & BEAR LLP, 2040 MAIN STREET, FOURTEENTH FLOOR, IRVINE, CA, 92614, US

(21) Appl. No.: 11/916,982

(22) PCT Filed: Jun. 6, 2006
(86) PCT No.: PCT/AU06/00786

§ 371 Date: Jun. 20, 2008

Related U.S. Application Data
(60) Provisional application No. 60/688,738, filed on Jun. 8, 2005.

(51) Int. Cl. B41F 1/18

(52) U.S. Cl. 101/450.1

(57) ABSTRACT

A patterning process, including applying pressure to and removing pressure from one or more regions of a substance to transform a phase of one or more regions of the substance, the transformed one or more regions having respective predetermined shapes representing a predetermined pattern. The patterning process can be used to form nanoscale patterns in substances without requiring the use of photoresist or conventional optical or electron-beam lithography, thus avoiding the limitations of those techniques.

### CROSS-REFERENCE TO RELATED APPLICATIONS

This application is the U.S. National Phase under 35 U.S.C. § 371 of International Application No. PCT/AU2006/000786, filed Jun. 7, 2006, designating the United States and published in English on Dec. 14, 2006, as WO 2006/130914, which claims priority to U.S. Provisional Application No. 60/688,738, filed Jun. 8, 2005.

### FIELD

The present invention relates to a patterning or lithographic process that can be used as an alternative to standard lithographic processes for transferring a pattern to a substance or substrate such as a semiconductor wafer, for example.

### BACKGROUND

The rapid progress in microelectronics is often represented by Moore's Law, which predicts that the number of transistors per integrated circuit will continue to double every couple of years. This doubling requires the physical size of each transistor to decrease with each successive generation of integrated circuits. However, the difficulty of achieving this shrinkage has increased dramatically, to the point where it may not be economically feasible to continue to follow Moore's Law due to exponential increases in complexity and the time required to develop new generations of integrated circuits. On the other hand, the enormous demand for smaller and/or faster electronic, optical, and/or other types of devices may justify such high development costs in some cases. Yet the challenges of developing ever smaller devices remains considerable, particularly as the characteristic dimensions of such devices enter the nanometer scale.

In particular, the lithographic processes used to pattern the layers of an integrated circuit or other type of chip by defining the lateral dimensions of device and circuit features face ever more difficult challenges, as described in the 2004 Update to the International Technology Roadmap for Semiconductors, available at http://www.itrs.net/Common/2004Update/2004_{—}07_Lithography.pdf. Processes used to define these lateral dimensions are referred to generally in the art as patterning or lithographic processes (the latter by analogy with traditional printing processes). Thus a patterning or lithographic process is generally understood as one that establishes a desired arrangement or layout of one or more two-dimensional regions of arbitrary shape on the surface of a substance, typically a semiconductor wafer, which may already be partly processed to include one or more modified and/or deposited layers. Typically, the ‘patterned’ substance is then further processed to provide a corresponding pattern of modified or deposited regions. For example, a layer of another substance may be selectively deposited over only those one or more regions, or their complement (i.e., over everywhere except these regions, or to modify either those regions or their complement.

The desired pattern is said to be ‘transferred’ to the substance, and the patterned surface can be considered to reproduce the pattern. Additionally, the word “pattern” should be understood as including a situation where only one region is defined, and it is not necessary that the pattern or each region have any symmetry, regularity or repetition. Despite recent advances made in resolution enhancement technology and maskless, immersion, extreme ultraviolet, electron beam projection, and proximity electron lithographic processes and systems, many of the requirements of near future lithography have no known manufacturable solutions. There is therefore a need for new technologies for patterning or lithographic processes or otherwise producing one or more patterned regions of a substance.

Additionally, there are a range of other microelectronic and optoelectronic applications where lithographic or other patterning processes are needed but where the primary focus is on low cost and/or large area patterning rather than small feature size. Examples of such applications include flat panel displays (FPDs), photovoltaic devices, hybrid circuits, microelectromechanical systems (MEMS), integrated communication circuits, microelectronic modules, radio frequency identification (RFID) tags, and thin film transistors (TFTs) for liquid crystal display (LCD) displays, including TV screens. Whereas many of these applications involve patterning silicon or other semiconductor materials, there are a growing number of applications based on organic or plastic materials that are flexible. In such cases, patterning of materials can be achieved through, for example, microcontact printing, microtransfer patterning and liquid embossing, or by using optical lithography, but with features that allow large area patterning at moderately high resolution. However, there are a number of challenges in these areas that relate to cost-efficiency, reproducibility, lateral resolution and feature definition, the reduction of stitching errors for large area patterning, the fabrication of master dies and ‘stamps’ that do not degrade substantially over extended use, the need to work with substrate materials that may not be process-compatible with silicon, as well as reducing the number of process steps and associated high cost capital equipment required to achieve the desired patterning of the substrate.

It is desired, therefore, to provide a patterning process, that alleviates one or more of the above difficulties, or at least provides a useful alternative.

### SUMMARY

In accordance with the present invention, there is provided a patterning process, including:
applying pressure to and removing pressure from one or more regions of a substance to transform a phase of one or more regions of said substance, the transformed one or more regions having respective predetermined shapes representing a predetermined pattern.

Preferred embodiments of the present invention can be used to produce selected-area, pressure-induced phase changes in a substance that can result in one or more amorphous and/or crystalline phases in selected areas that exhibit different electrical, thermal, mechanical, optical, chemical, material removal, and other properties with respect to one or more surrounding, untransformed regions of the substance.

In one embodiment, the substance is silicon, and the process includes selective removal of one or more different phases of silicon by preferential wet chemical etching of those phases. The removed phases may be the transformed one or more regions, or one or more regions not transformed. In this embodiment, many of the steps required by standard optical lithography processes to transfer a pattern to silicon are eliminated.

The transformed regions of the substance, which may be a semiconductor and silicon in particular, may also exhibit different electrical and other properties to the untransformed substance, such as but not limited to electrical conductivity, refractive index, surface acoustic wave velocity, Young's modulus, etc, and one or more of these modified properties can lead directly to desired active or passive device functionality. The realisation of such device functionality may require the removal of the transformed or untransformed regions, but this is not necessarily the case.

In one embodiment of the present invention, there is provided a means of causing pressure-induced phase change in one or more regions of a substance, where the shape of at least one transformed region is controlled not only in the two-dimensional x-y plane, but also in a third, orthogonal z-dimension, to produce a transformed region having a desired three-dimensional shape. This is achieved by control of the application and/or release of pressure, taking into account the shape of the pressure applicator. The shape of the transformed region may be relatively complex, such as, for example, a sphere, polyhedron and the like.

The present invention also provides a system having components for executing the steps of any one of the above processes.

### BRIEF DESCRIPTION OF THE DRAWINGS

Preferred embodiments of the present invention are hereinafter described, by way of example only, with reference to the accompanying drawings, wherein:

FIG. 1 is a state diagram illustrating the various phases of silicon that can be obtained by the application and removal of pressure in accordance with a preferred embodiment of the present invention;

FIGS. 2 and 3 are schematic plan and side views, respectively, of a crystalline silicon wafer having a thin surface layer of relaxed amorphous silicon;

FIGS. 4 and 5 are schematic plan and side views, respectively, of a stamping tool or die including raised surface features or projections for applying and removing pressure from corresponding regions of a substance in accordance with a preferred embodiment of the present invention;

FIGS. 6 and 7 are schematic side and plan views, respectively, illustrating the application of the die to a portion of the silicon substrate of FIGS. 2 and 3, but prior to the application of pressure to the substrate;

FIGS. 8 and 9 are schematic side and plan views, respectively, illustrating the phase transformation in corresponding regions the surface layer resulting from the application of pressure to the substrate by the projections on the die;

FIGS. 10 and 11 are schematic side and plan views, respectively, illustrating the further changes in phase of the transformed regions resulting from the controlled removal of pressure from those regions;

FIG. 12 is a schematic cross-sectional side view illustrating yet further changes in phase resulting from annealing the transformed regions of the surface layer;

FIG. 13 is a schematic cross-sectional side view of the wafer following removal of the untransformed regions of the surface layer by wet etching;

FIG. 14 is a flow diagram of a preferred embodiment of a patterning process;

FIG. 15 is an AFM image showing an array of amorphous silicon islands on a crystalline Si-I substrate, formed by the slow removal of pressure applied by a spherical indenter to corresponding regions of a Si-I substrate;

FIG. 16 is a graph of an AFM line scan across a row of the amorphous islands shown in FIG. 15, indicating that each island is about 450 nm high, and about 2.5 μm wide;

FIG. 17 is an AFM image showing an array of islands of the high-pressure phases Si-III/Si-XII on a crystalline Si-I substrate, formed by the rapid removal of pressure applied by a spherical indenter to corresponding regions of a Si-I substrate;

FIG. 18 is a graph of an AFM line scan across a row of the islands shown in FIG. 17, indicating that each island is about 800 nm high, and about 2.5 μm wide;

FIG. 19 is an AFM image showing an array of islands of the high-pressure phases Si-III/Si-XII on a crystalline Si-I substrate, formed by the slow removal of pressure applied by a spherical indenter to corresponding regions of a relaxed a-Si layer;

FIG. 20 is a graph of an AFM line scan across a row of the islands shown in FIG. 19, indicating that each island is about 300 nm high, and about 3 μm wide;

FIG. 21 is an AFM image showing an array of openings or recesses formed by the slow removal of pressure applied by a spherical indenter to corresponding regions of a relaxed a-Si layer;

FIG. 22 is a graph of an AFM line scan across a row of the recesses shown in FIG. 21, indicating that each recess is about 120 m deep, and about 2.5 μm wide;

FIG. 23 is an AFM image showing an array of amorphous silicon islands formed by the rapid removal of pressure applied by a Berkovich indenter to corresponding regions of a Si-I substrate;

FIG. 24 is a graph of an AFM line scan across a series of the amorphous islands shown in FIG. 23, indicating that each island is about 60 nm high, and about 1 μm wide;

FIG. 25 is an AFM image showing an array of islands of the high-pressure phases Si-III/Si-XII on a crystalline Si-I substrate, formed by the slow removal of pressure applied by a Berkovich indenter to corresponding regions of a Si-I substrate; and

FIG. 26 is a graph of an AFM line scan across a row of the islands shown in FIG. 25, indicating that each island is about 50 nm high, and about 1 μm wide;

FIG. 27 is an AFM image of an extended linear or line feature of amorphous silicon formed by applying and rapidly removing pressure from a linear array of overlapping regions, followed by etching to preferentially etch the untransformed crystalline silicon; and

FIG. 28 is an AFM line scan across the line of amorphous silicon, indicating that the line is about 250 nm high and almost 2 μm wide.

### DETAILED DESCRIPTION OF THE PREFERRED EMBODIMENTS

Crystalline diamond-cubic silicon (also referred to as Si-I, the ‘common’ silicon phase produced in wafer form for the manufacture of microelectronic devices) undergoes a series of phase transformations during mechanical deformation. High-pressure diamond anvil experiments have shown that crystalline diamond-cubic Si-I undergoes a phase transformation to a metallic β-Sn phase (also referred to as Si-II) at a pressure of ˜11 GPa, as described in J. Z. Hu, L. D. Merkle, C. S. Menoni, and I. L. Spain, Phys. Rev. B 34, 4679 (1986), and because Si-II is unstable at pressures below ˜2 GPa, the Si-I undergoes further transformation during pressure release.

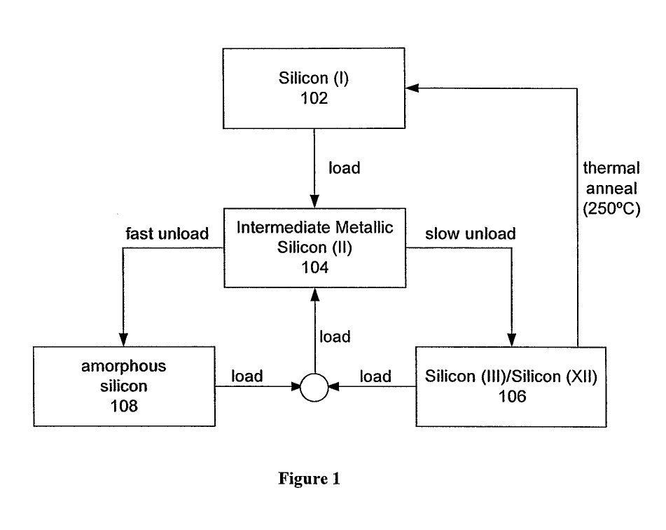

These phase transformations have also been observed to occur during a process referred to as indentation, wherein an extremely hard indenter tip is pressed into the surface of a material by increasing application of force (referred to as the loading or applying phase or step of the indentation process), and this force is subsequently decreased (referred to as the unloading or releasing phase or step of the indentation process) and the indenter tip removed from the deformed or indented surface. Indentation as described above is a well-established technique for evaluating material properties of substances, hardness in particular. FIG. 1 summarises the phase transformations that occur during indentation loading and unloading of Si-I 102. As in diamond-anvil experiments, the initial Si-I phase 102 transforms to the Si-II phase 104 under pressure; i.e., during loading. On unloading, the Si-II phase 104 undergoes additional transformations to form either the crystalline phases Si-XII/Si-III 106 or an amorphous phase (a-Si) 108, depending on the rate of pressure removal. Fast unloading leads to the formation of a-Si 108, whereas slow unloading results in the formation of Si-XII/Si-III 106.

a-Si is an unusual phase in that it exhibits markedly different properties, depending on how it has been formed. In particular, a-Si can exist in one of two states: an ‘unrelaxed’ state (e.g., as-deposited or directly after formation by ion-implantation at room temperature), and a ‘relaxed’ state (e.g., formed by annealing unrelaxed a-Si at 450° C.), and these two states have different properties. In particular, as-implanted (unrelaxed) a-Si has been found to be significantly softer than Si-I, whereas annealed (relaxed) a-Si has been found to have very similar mechanical properties to those of the crystalline state Si-I. The reason for these differences is not known.

For example, a continuous layer of unrelaxed a-Si can be prepared by ion-implantation of crystalline Si-I 102 with 600 keV Si ions to a fluence of at least about 3×10¹⁵ ions cm⁻² at liquid nitrogen temperature. After implantation, a sample produced in this manner can be annealed for 30 minutes at a temperature of 450° C. in an argon atmosphere to cause the unrelaxed a-Si to transform to ‘relaxed’ a-Si. The thicknesses of the relaxed and unrelaxed amorphous layers produced under these conditions have been measured to be ˜650 nm by Rutherford backscattering (RBS) with 2 MeV helium ions, demonstrating that the annealing process is not sufficient to recrystallize the a-Si layer, and hence the layer remains amorphous. Thus the relaxed and unrelaxed states are both amorphous states of silicon.

As described in International Patent Application No. PCT/AU2004/001735, indentation of a layer of unrelaxed a-Si does not transform the unrelaxed a-Si into any other phases, presumably because the relatively soft unrelaxed a-Si flows out from under the indenter tip and consequently does not reach the pressure required to initiate phase transformation.

In contrast to unrelaxed a-Si, indentation of a relaxed a-Si layer can cause phase transformations during both loading and unloading. On loading, relaxed a-Si transforms to the metallic Si-II phase 104. On unloading, the Si-II phase 104 undergoes further transformations, depending on the rate of pressure release. Slow unloading causes the Si-II to transform to Si-XII/Si-III 106 (and possibly a relatively small amount of a-Si within these phases), whereas fast unloading causes the Si-II to transform to a-Si. It is not clear whether the a-Si formed on unloading is in the relaxed or unrelaxed state, but this does not appear to influence its ability to transform to Si-II on subsequent reindentation, presumably because the small indent-induced amorphous region is confined under the indenter and surrounded by material that does not flow on the application of pressure. Consequently, even if this amorphous material was in the unrelaxed state, it could not flow out from under the indenter, and would therefore be subjected to the high pressures required to transform it to the Si-II phase 104.

Moreover, heating the region of phase transformed Si-XII/III material in the relaxed amorphous Si layer to temperatures above 200° C. and up to 450° C. for 30 minutes causes the Si-XII/III phase to undergo a further transformation to the Si-I phase. Significantly, any amorphous Si within the transformed region containing Si-XII/III is also transformed to Si-I. However, the relaxed a-Si that surrounds the indented region (i.e., relaxed a-Si that has not undergone any phase transformation) does not undergo the thermally-induced phase transformation to Si-I when heated to temperatures up to 450° C. for 30 minutes.

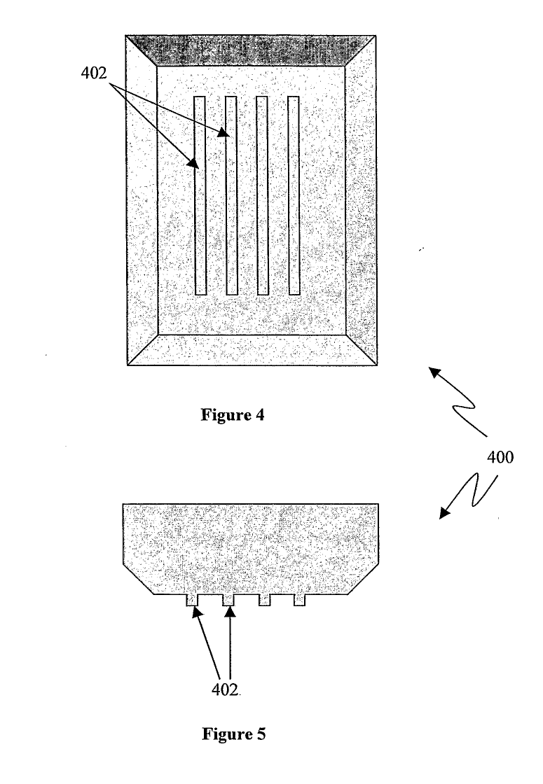

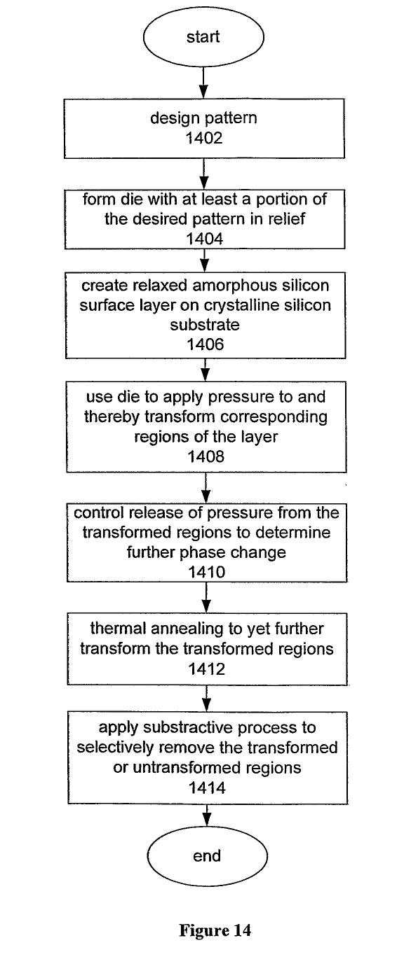

As shown in FIG. 14, a lithographic or patterning process based on these observations has been developed. The process begins by designing or otherwise producing a desired pattern at step 1402. This can be done using standard physical layout or mask design software, such as L-edit, described at http://www.tanner.com/EDA/products/ledit/default.htm, to generate pattern data representing the desired pattern. At step 1404, a stamping tool or die is produced from the pattern data to reproduce the desired pattern (in relief) as raised surface features or projections on an otherwise substantially planar surface. Alternatively, if the pattern consists of one or more repeating features, the die can reproduce a portion of the desired pattern that can be repeated to reproduce the entire pattern. For example, FIGS. 4 and 5 are schematic plan and cross-sectional side views, respectively, of a simple die 400 having a series of 10 nm wide lines 402 separated by 100 nm. Such a die is preferably manufactured from or coated with a material that is significantly harder than the substrate material. In the described embodiment where the substrate is elemental silicon, the die can be made from or coated with a material such as boron nitride, silicon carbide, diamond, or a diamond-like material to improve the hardness of the projections and thus the durability of the die. The pattern, or a portion of the pattern, is transferred in relief to the die material using a standard lithographic process in which die material surrounding the relief pattern is removed to a desired depth by a wet chemical or, preferably, a dry etching process. It will be apparent to those skilled in the art that the lithographic process can include the production of an optical lithography mask from the pattern data. Alternatively, the pattern data can be used to determine the path of an electron in an e-beam lithography tool.

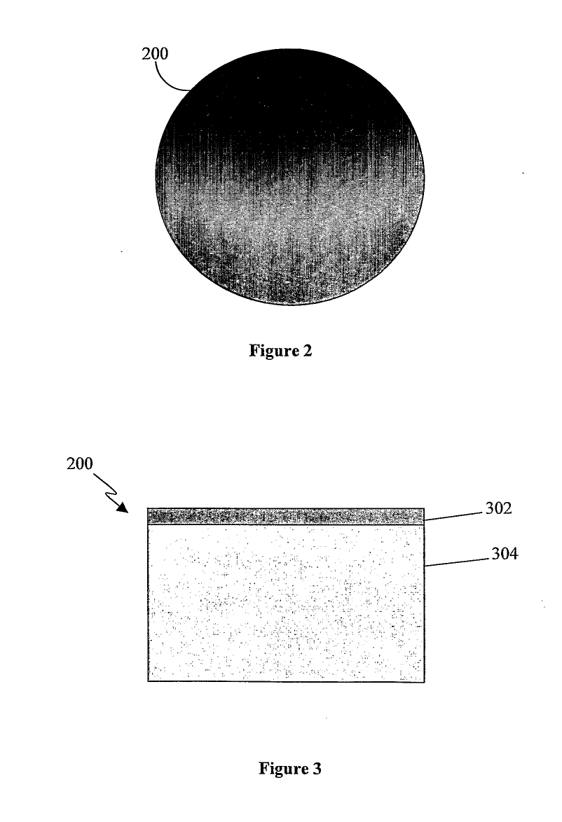

FIGS. 2 and 3 are plan and cross-sectional side-views, respectively, of a silicon wafer 200, prepared at step 1406 by creating a relaxed amorphous silicon surface layer 302 on the crystalline silicon substrate 304. For example, the ion implantation and annealing steps described above can be used to form a 650 nm surface layer of relaxed a-Si on a crystalline Si-I substrate. If a different layer thickness is required, the beam energy and ion fluence can be adjusted accordingly, as will be apparent to those skilled in the art.

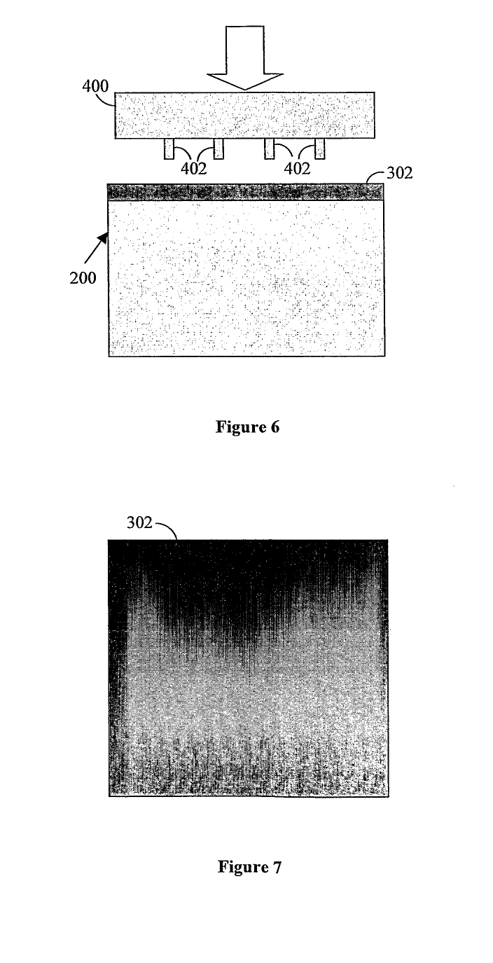

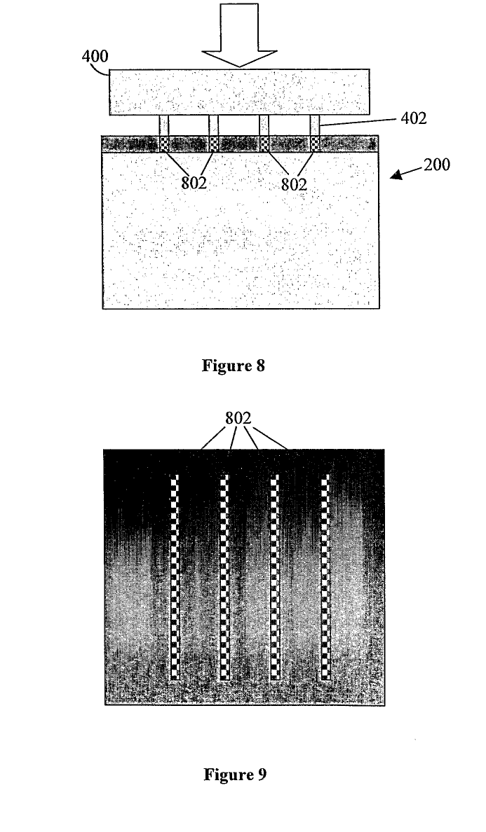

Referring to FIG. 14, at step 1408 the die 400 that has been patterned to reproduce at least a portion of the desired pattern is used to apply pressure to corresponding regions of the surface layer 302. As shown in FIG. 6, this is achieved by applying the die 400 to contact the surface layer 302, and then applying pressure, preferably but not necessarily in a direction substantially normal to the surface layer 302, but in any case such that there is no substantial lateral movement of the die 400 with respect to the surface layer 302. The projections 402 of the die 400 contact corresponding regions of the surface layer 302 and apply pressure to those regions. As shown in FIGS. 8 and 9, sufficient pressure (at least 11 GPa) is applied to at least the regions 802 immediately under the projections 402 of the die 400 to transform those regions to the metallic silicon-II phase. The maximum pressure applied to the surface layer 302, the direction in which that pressure is applied, and to some extent the indenter shape determine the depth and lateral extent of the transformed regions.

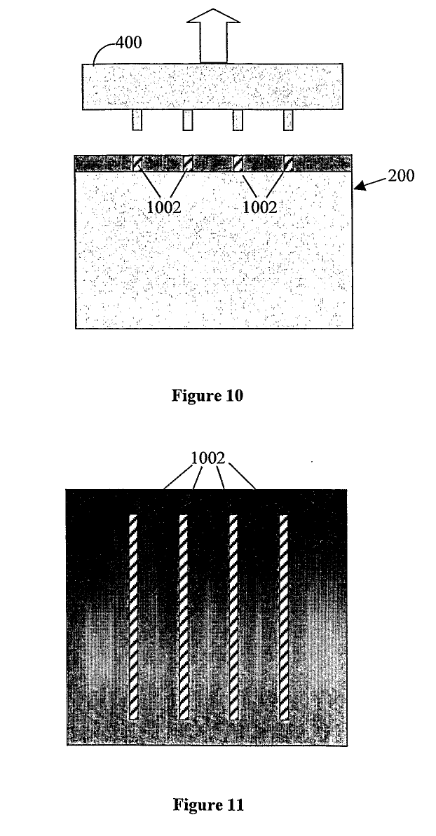

It will be apparent to those skilled in the art that although the transformed regions are represented schematically in FIG. 10 as being rectangular in shape, the regions actually transformed in practice will be those regions within the stress field produced within the surface layer 302 (and potentially also the substrate 304 beneath the surface layer 302) that are subjected to a pressure equal to or greater than that required to transform the phase of those regions. Typically, those regions are expected to be quasi-spherical or part-spherical in shape in the case of a highly localised, point-like projection such as an indenter tip, for example. Additionally, in many cases the shape of the tip can be at least partly transferred in mirror-image to the indented surface by plastic deformation of that surface, and this deformation itself can be useful for some applications, including MEMS structures, and surface texturing of solar cells, as described below.

At step 1410 in FIG. 14, the pressure applied by the die 400 is released in a controlled manner such that the rate of pressure release from the regions transformed by the projections 402 provides the desired end phase or phases to a desired depth. In the described embodiment where the surface layer 302 is relaxed amorphous silicon, the pressure is released relatively slowly (less than about 3 mN s⁻¹ in the case of a 4.21 μm radius spherical indenter tip) so that the end phases in the localised regions 1002 are predominantly Si-III/Si-XII, as shown in FIGS. 10 and 11. Alternatively, if the transformed regions were originally crystalline, then the pressure can be released relatively quickly, if the desired end phase is amorphous silicon (but may additionally contain a relatively small proportion of Si-III/Si-XII).

The application and subsequent removal of pressure by the die as described above is referred to herein as a ‘stamping’ process. In this specification, the word ‘stamping’ refers to a process whereby a stamping tool, die, indenter tip, or any other type of tool, stylus instrument, or other physical entity is brought into contact with one or more corresponding regions of a substance, and then is used to apply pressure to at least the regions immediately underneath the regions of contact. As described above, although the pressure need not be applied in a direction normal to a surface of the substance, the pressure is applied in such a way that, during the application of that pressure, there is no substantial degree of lateral movement between the stamping tool or die or indenter tip. Thus a stamping process can be contrasted to a dragging or scratching process whereby a tool or other instrument is moved across a surface while applying substantial pressure to that surface. In the case of scratching, the result is generally the fracture and removal of portions of the surface, resulting in the formation of trough, scratch, or other form of mechanical damage along that surface. Although, in the case of stamping, it is possible to apply pressure to the surface in a direction that is not normal to that surface in order to form phase transformed regions with a particular shape or orientation, one distinction is that the tool or instrument applying that pressure does not move relative to the substrate, other than by any small degree of elastic or plastic deformation of that surface. However, one exception to this is the application of pressure by a tool having a rolling component for contacting the surface. By analogy with the macroscopic world, such a tool could be considered to be structurally similar to a spherical ball point pen or a cylindrical steam roller. Although this form of tool can be moved across the surface (by translating the tool or the surface) while applying pressure to that surface, from the perspective of the surface to which the tool is applied, each contacting portion of the tool applies pressure substantially normal to the surface without scratching or dragging, and thus the application and removal of pressure using such a tool can nevertheless be considered to be a stamping process.

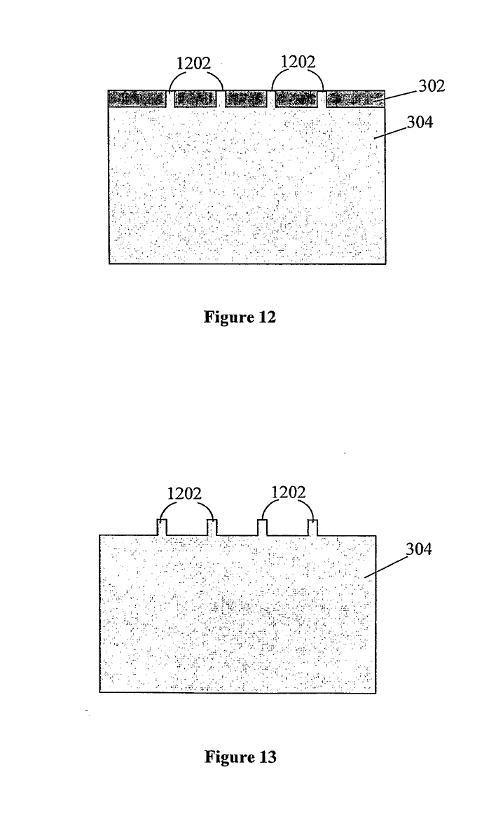

At step 1412, if the selected patterned regions 1002 have been substantially transformed from amorphous silicon to the Si-III/Si-XII phases, the entire wafer 200 can be subjected to thermal annealing at temperatures above about 200° C. and up to about 450° C. (and preferably around 250° C.) for 30 minutes in order to transform the silicon-III/silicon-XII regions into crystalline silicon-I regions 1202, as illustrated in FIG. 12. This optional step is generally preferred because it can improve the effective contrast between the transformed and untransformed regions (e.g., by increasing the difference in etching rates), and/or because the Si-I phase is more thermodynamically stable.

The patterning process has been described above in terms of transferring a desired pattern to a relaxed amorphous surface layer 302 on a crystalline silicon substrate 304. However, it will be apparent to those skilled in the art that the patterning process can be employed to pattern a wide variety of substrate types and substances or materials. In Si, the starting material can be relaxed a-Si or one or more phases of crystalline Si, either in single crystal or poly-crystalline form, including Si-I, Si-III, Si-IV, and/or Si-XII. In an alternative embodiment, the surface layer is crystalline, and the pattern is transferred to the surface layer as one or more substantially amorphous silicon regions formed by rapidly releasing pressure applied to those regions, as described above. For example, the wafer to which the pattern is to be applied can be a crystalline silicon wafer having an epitaxial surface layer of crystalline silicon formed over a crystalline silicon substrate which may have a different doping level than the surface layer. In particular, the doping level of the surface layer may be substantially higher than that of the substrate. Alternatively, the wafer to which the pattern is to be transferred can be a silicon-on-insulator (SOI) wafer having an insulating silicon dioxide layer disposed between the crystalline surface layer and the underlying substrate. Alternatively, the wafer could be a silicon-on-sapphire wafer, or the process could be applied to a thin film of silicon deposited on a ceramic, polymer, glass or other type of substrate. Alternatively, the wafer could be a standard Si-I wafer without any surface layer, and the patterning process used to pattern the wafer by forming one or more regions substantially consisting of one or more other phases of silicon.

In a further alternative embodiment, the pattern is transferred to the substrate using a pointed or spherical indenter, where the indenter size is equal to or smaller than the smallest feature size of the pattern. In this alternative embodiment, the indenter is moved over the substrate, preferably under computer control, and repeatedly lowered to stamp the substrate at a plurality of locations in order to collectively reproduce the desired pattern. At each location the intender is lowered to contact the substrate, and then the indenter applies pressure to the substrate without any substantial degree of relative movement between the indenter and the substrate. In general, the locations at which the indenter contacts the substrate are such that at least some of the resulting transformed regions will overlap to form one or more extended transformed regions in order to reproduce corresponding extended features of the desired pattern. In yet a further alternative embodiment, the pointed or spherical indenter tip is lowered to apply pressure to the substrate and then dragged along the surface of the substrate to produce a desired pattern of transformed material along the path traversed by the indenter. However, the first, die-based embodiment is preferred in cases where the features are predominantly narrow lines or dots.

In yet another further embodiment, the die and indenter-based processes are combined, so that a die representing a portion of the desired pattern in relief is fabricated and used to reproduce a portion of the desired pattern on the substrate (if necessary, by using a step and repeat process to repeatedly transfer the die portion of the pattern to the substrate), and the remainder of the desired pattern transferred using the indenter, either by stamping without substantial lateral movement, or by dragging along the surface, as described above.

In each embodiment, the above steps produce a patterned surface comprising localised regions of one phase of silicon 1002 or 1202 in a layer of another phase of silicon 302.

Depending on the shape and dimensions of the pressure applicator and the force applied to the applicator, the localised regions, 1002 and 1202, can be of nanoscale dimensions, and have physical properties that differ from those of the surrounding surface layer 302. These modified properties can include electrical, optical, mechanical, and/or other material properties, and can provide the basis of one or more active or passive elements or components of an electrical, optical, mechanical, and/or other type of device. Furthermore, the transformed and untransformed phases can have significantly different removal rates when subjected to a subtractive process such as chemical etching, as described below. For many applications, it is preferred that the transformed regions extend vertically through a surface layer, but this may not be necessary for many other applications.

Depending on application, the patterning process can be continued at step 1414 by applying a subtractive process to selectively remove either the localised regions 1002 or 1202 or the surrounding regions of the layer 302 (i.e., those portions of the surface layer 302 to which pressure was not applied, as shown in FIG. 13). As described in the literature (see for example, Beadle et al, ‘Quick Reference Manual for Silicon Processing, Wiley, New York (1985); ‘Semiconductor Silicon’, Ed Haff et al., 1973; and ‘Silicon’, Inspec, Institute of Electrical Engineers, London, 1988), a wide variety of etchants and etching processes have been developed for selectively or preferentially removing silicon layers of different phases, such as amorphous or crystalline silicon phases, of different doping type and dopant concentration, of different crystallographic orientation, and layers containing different types of defects or impurities. For example, depending on the doping type (p- or n-type) and doping concentration in the crystalline silicon, it is possible to use wet etching (using appropriate mixtures of nitric, hydrofluoric, and acetic acid, again depending on doping type), as well as applying an electrical potential to the etch surface, to give almost 100% selectivity for removing amorphous silicon compared with the crystalline phase. Preferential removal of crystalline silicon over amorphous silicon is not as selective but rate differences of several times are possible between the two phases. In addition, a hydrogen plasma has also been found to be very selective at removing amorphous silicon compared with n-type silicon. Using such methods, amorphous or crystalline silicon regions can be preferentially removed. The subtractive process step can thus leave either a pattern of raised surface features that correspond to the transformed regions 1002 or 1202, or of the remaining layer surrounding the (now removed) localised transformed regions 1002 or 1202. If an SOI substrate is used, the resulting pattern of silicon regions can be partly or completely free-standing on the silicon dioxide layer, which can be removed if desired to partially or completely free the silicon structures, allowing the structures to move or be completely separated from the remaining substructure or layer 302.

In addition to providing a cost-effective process for transferring a pattern directly onto silicon that can eliminate many of the costly lithographic steps currently used, the remaining regions, 1002 and 1202, can be used as or to directly fabricate passive or active elements or components for electronic, optical, mechanical, and/or other types of devices by exploiting their electrical, optical, and/or other properties.

Moreover, the remaining surface features 1002 and 1202 can also be used as a patterned mask in order to selectively introduce impurities or otherwise process the exposed regions of the crystalline silicon substrate 304. For example, the exposed regions of the substrate 304 between the patterned surface features 1202 can be used for metallisation/lift-off, further etching, and/or selectively introducing impurities into the substrate 304. Thus the patterning process allows silicon to be patterned without the use of photoresist. This is particularly advantageous because silicon is compatible with CMOS processing, it's use does not introduce a new material, it can be patterned, etched, and used as a barrier to dry etching, and may not need to be stripped from the wafer, depending on application. Hence, it potentially removes the requirement for metallization and has many fewer processing steps than conventional resist-based lithographic processes. Moreover, the patterning process allows patterns including small features to be formed without consideration/limitation of the wavelength of light, which needs to be considered when photoresists are used.

By comparison with standard lithographic techniques, the patterning process provides a variety of advantages. In particular, the size and shape of the resulting patterns are limited only by the die construction for a single indentation step or by stitching/alignment errors if a moving indenter and/or die is used to produce overlapping transformed regions. By comparison with traditional photoresists, the use of silicon as a masking material is particularly advantageous, as the silicon masking layer does not need to be stripped from the wafer, but can remain in the final device or circuit, and can even constitute an active or passive layer providing electronic, optical, mechanical, and/or other functions.

Additionally, the simple physical contact involved simplifies processing, and may be substantially cheaper than many existing nanoscale lithographic processes. Moreover, the process is not restricted to standard semiconductor wafers, but can be applied to pattern regions of a wide variety of materials and substrates, including large scale substrates such as LCD display panels and solar cell panels, for example. The transformed substance may be in the form of a layer attached to a substrate, which may be, for example, a semiconductor, ceramic, glass, or polymer.

Although the patterning process has been described above in terms of a silicon substrate, it will be apparent to those skilled in the art that the process is not limited to silicon, but can be applied to any material capable of being phase transformed by the application and removal of pressure. Such materials include other semiconductors (including Ge, GaAs and InSb, for example) and ceramics (including SiC, a-quartz, and silica glass).

Finally, as described above, the maximum applied pressure can be controlled to control the spatial extent of the transformed regions. Moreover, due to the three-dimensional distribution of the stress field, the release of pressure can be controlled in a more complex manner to change the effective rate of pressure release in two or more sub-regions of each transformed region. For example, a portion of the force applied by the pressure applicator (whether indenter tip, die, or other form of applicator) can initially be released relatively quickly to rapidly release pressure from the transformed regions at the outer extent of the stress field to a pressure value below a critical pressure threshold (e.g., <11 GPa in the case of elemental silicon and, in the case of a 4.2 μm radius spherical indenter, using a release rate greater than about 3 mN S⁻¹), thus causing those sub-regions to transform to the amorphous phase while regions closer to the source of the pressure remain above threshold, and thus in the case of silicon, remain Si-II. The residual applied pressure can then be released relatively slowly (i.e., less than about ˜3 mN S⁻¹ under the conditions specified above) to transform the remaining Si-II regions to Si-III/Si-XII. The result is a buried amorphous region. Conversely, the process could be used to provide a buried crystalline region beneath amorphous silicon. It will be apparent that an almost infinite variety of possible combinations of partial and/or complete pressure application and/or removal and their rates of application and/or removal could be used to further control the final phase(s) and/or their spatial distributions, depending on the phase transformation behaviour of those phases and in particular the relevant threshold pressures for effecting the respective phase transformations. For example, the pressure could be partially released and partially re-applied before complete release, and the substance could even be heated at one or more stages of this process while under pressure to further control the phase transformations.

Examples of selected applications (mainly for silicon substrates) of the patterning process are described below.

### Microelectronic Circuits

The patterning process can be used in the production of microelectronic integrated circuits by selecting an appropriate substrate, applying pressure to and removing pressure from selected regions of the substrate to modify the phase of those regions, and then selective etching to remove either the modified regions, or the unmodified regions surrounding the modified regions.

The thickness of the remaining features can be selected as required by adjusting the applied pressure, the etch parameters, or both. For example, when used as an etch mask, the height of the mask features can be selected by considering the relative etch rates of the untransformed substrate material and the transformed features. When used as a gate in a transistor, the feature height can be selected to be as small as 25 nm. The patterning process can be used to produce lines of lengths exceeding 1 mm. The line pitch, being the sum of the width of each line and the spacing between adjacent lines, can be as small as 50 μm, with a line width of 25 nm, and a line spacing of 25 nm.

Further examples include patterning gates by depositing a layer of amorphous silicon on a polysilicon layer, using the patterning process to create parallel lines of crystalline silicon in the amorphous silicon, or vice versa, and then removing the remaining amorphous silicon or crystalline silicon, as desired.

### Flat Panel Displays

Currently, active matrix flat panel displays use thin film transistors (TFTs) with polycrystalline silicon channels to control liquid crystal displays (LCDs), and also polymer organic LEDs (PLEDs). The silicon is deposited as a thin film of amorphous silicon that is subsequently transformed to poly-crystalline silicon in selected regions corresponding to the channels of the TFT's. The flat panel display industry has considered directly depositing crystalline silicon, but there are difficulties with producing large area thin poly-crystalline silicon films of acceptable quality. In current technology, as-deposited amorphous silicon is transformed to polycrystalline silicon by UV laser annealing in the regions of the TFT channels, but this has turned out to be a high cost and low yield process. However, the patterning process described above can be applied to transform selected regions of an amorphous silicon layer into (poly)crystalline silicon, in which TFTs or other devices can be made. Further, by control of doping, starting material properties, pressure application and release rates, annealing and other properties, the electronic properties of the converted poly-crystalline zones can be controlled as desired. Additionally, the entire layer of amorphous silicon can be substantially transformed to polycrystalline silicon if desired by applying in excess of 11 GPa of pressure to the entire layer and then relatively slowly releasing that pressure. The pressure can be applied to the entire layer by a single die in the form of a single region having dimensions at least as large as the lateral dimensions of the layer, or by repeated application of a smaller die, indenter, and/or other form of pressure applicator to respective regions of the layer until substantially the entire layer is substantially transformed.

### Flexible Microelectronic Circuits

Currently, flexible ICs are produced on high-cost specialty polymer substrates using inkjet and other high cost deposition technologies. However, a silicon film can be deposited on a plastic substrate at relatively low temperatures, and the patterning process described herein can then be used to change the electrical properties of selected regions of the film to define conducting (crystalline silicon), insulating (amorphous silicon) and semiconducting (crystalline silicon) regions in the deposited silicon film.

### Solar Cells

For solar cell applications, the patterning process can be used to produce crystalline and/or amorphous regions in a single thin film of silicon. Thus a single thin film of silicon can be produced that includes many small area solar cells interconnected by conducting crystalline silicon and insulated by amorphous silicon. The provision of many small solar cells allows additive voltages and lower currents, providing significant advantages in cost and performance over standard technologies, which are currently based on more costly and complex photolithography and laser scribing processes.

In addition, the patterning process can be used to form an etch mask for etching deep trenches in the polycrystalline surfaces of solar cells, and the trenches then filled with metal to make buried-contact metal conducting lines. These are much preferred to screen-printed metal lines because they provide a better electrical contact, and also shadow less of the solar cell surface from solar radiation. The etch mask can be formed by forming a phase that has a lower etch rate relative to the untransformed substance, in which case the transformed regions constitute the mask, or in the case of the transformed substance having a faster etch rate, the untransformed regions provide the etch mask. In either case, the less etched regions (either untransformed or transformed, as appropriate) can optionally be further transformed to another phase or phases if desired.

Solar cells have textured surfaces to reduce reflection of sunlight and thus improve their efficiency. Currently, this texturing is achieved by anisotropic etching of a poly-crystalline silicon wafer, a relatively expensive process. However, the patterning process described herein can be used in the process of texturing solar cells by patterning the surface of a silicon substrate to define an etch mask. Subsequent etching of the patterned surface creates a corresponding array of topographic surface features that reduce the reflectivity of the etched surface and thus constitute texturing. Additionally, the shape of the pressure applicator itself, which may be an indenter tip, can be used to permanently deform the silicon surface correspondingly, thus also reducing unwanted reflection and providing an additional or alternative form of texturing.

### EXAMPLE

Three types of silicon samples were prepared:
(i) a standard p-type single crystal silicon (100) wafer having a doping concentration of ˜10¹⁵ B cm⁻³;
(ii) samples identical to (i), but having a 650 nm unrelaxed amorphous surface layer formed by ion implantation as described above; and
(iii) samples identical to (ii), but having been annealed at 450° C. for 30 minutes to relax the amorphous surface layer.

An anisotropic etching solution of KOH was prepared from 75 grams of KOH pellets, 150 millilitres of de-ionized water, and 30 millilitres of isopropyl alcohol (IPA). This solution was used to etch the various samples as described below at a temperature of 80° C., with 20% IPA by volume added to the KOH solution to ensure a smooth surface finish. Two-dimensional arrays of indents were created in sample types (i) and (iii) using a UMIS indenter having a spherical tip of 4.3 μm radius at loads of up to 80 mN. The indenter samples were then etched in the KOH solution for two minutes at 80° C., as described above.

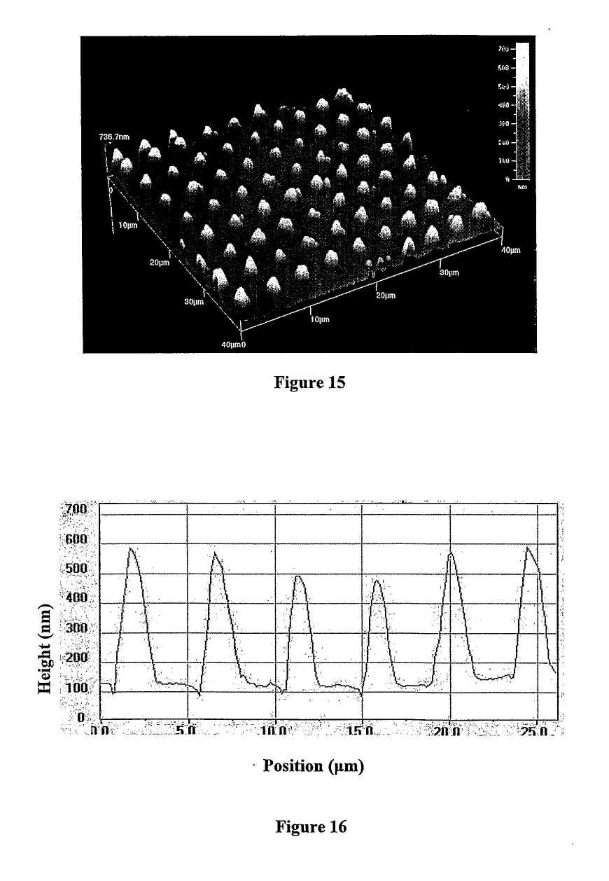

After etching, the resulting surface topography was visualised and measured using an atomic force microscope (AFM). FIGS. 15 to 22 include three-dimensional AFM images of the resulting surface topography, and one-dimensional topographic profiles of the etched surfaces.

A sample of type (i), i.e., Si-I (100) was indented by applying a pressure in excess of the ˜11 GPa threshold, followed by fast unloading (greater than about 3 mN S⁻¹ under these conditions) as described above to form the localised region of amorphous silicon. The UMIS indenter was programmed to perform this indentation step at a two-dimensional array of mutually spaced locations on the Si-I surface. The indented sample was then etched as described above.

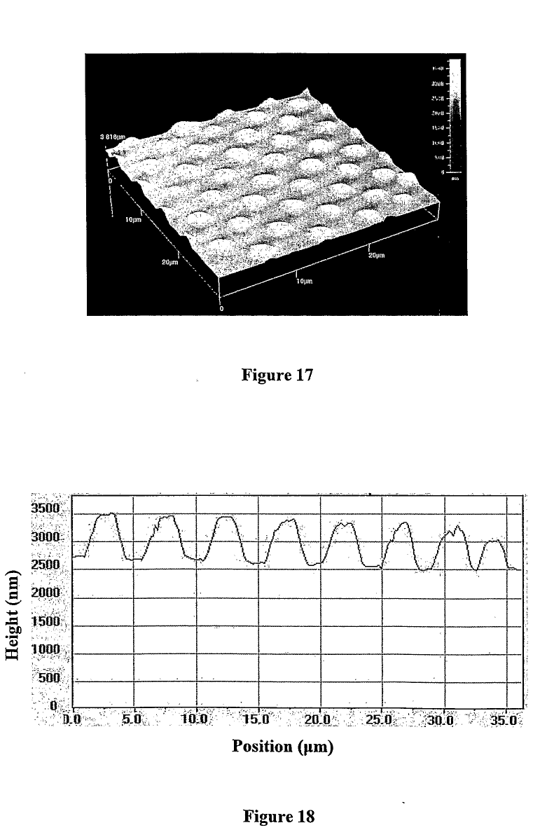

FIG. 15 is an AFM image of the resulting two-dimensional array of amorphous silicon islands projecting above a crystalline Si-I substrate. As expected from the bulk etching measurements, the amorphous silicon regions formed by fast unloading project above the crystalline silicon substrate as a two-dimensional array of islands due to their lower relative etch rate. As shown in FIG. 16, a corresponding AFM line scan across these amorphous silicon islands or mounds indicates that they are 450 nanometres high and about 2.5 microns wide. Performing the same steps in a new type (i) sample, but with slow unloading, produces an array of regions consisting of the mixed high pressure phases Si-III/Si-XII. As shown in FIGS. 17 and 18, the resulting surface topography after etching is again an array of raised islands having the same width as the amorphous islands described above, but projecting 800 nm above the Si-I substrate, nearly twice as high as the amorphous islands, suggesting that the etch rate of the mixed high pressure phases is substantially lower than that of the amorphous silicon islands shown in FIG. 15.

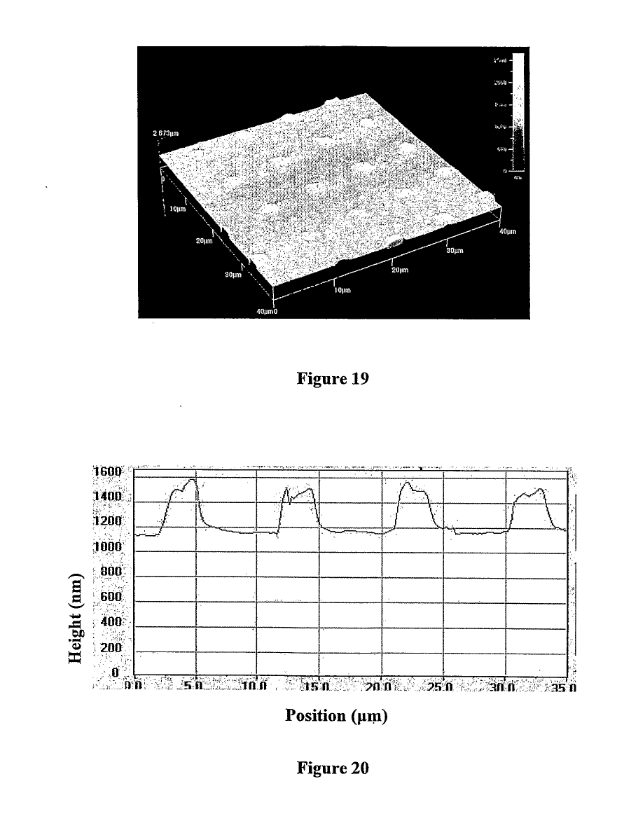

As described above, indentation of relaxed a-Si with slow unloading transforms the relaxed a-Si into the high pressure phases Si-III/Si-XII. As shown in FIGS. 19 and 20, etching of a type (iii) sample indented this way also resulted in the formation of a two-dimensional array of raised islands of Si-III/Si-XII, each island being about 300 nm high and having a width of about 2.5 μm.

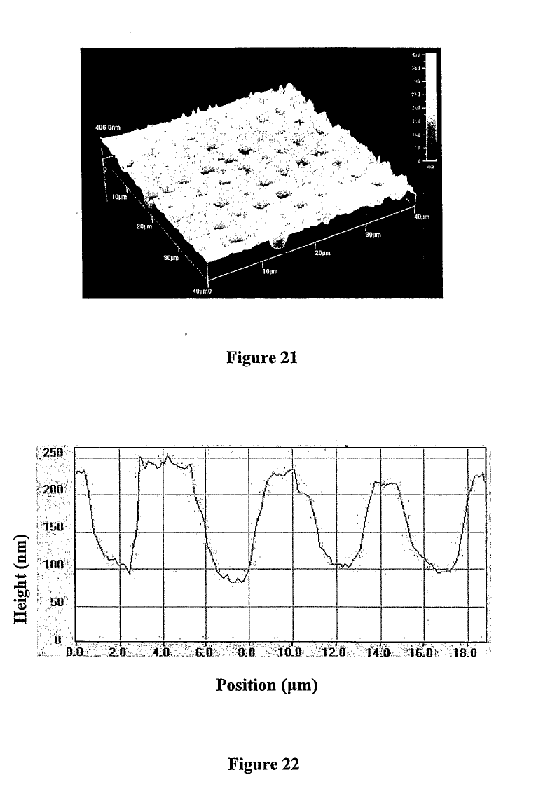

FIGS. 21 and 22 show the results of etching samples prepared in the same way, i.e., by indenting the relaxed a-Si with slow unloading, but including an annealing step whereby the indented sample was heated to 450° C. for 30 minutes to transform the high pressure phases to polycrystalline Si-I prior to etching. Due to the high relative etch rate of Si-I, the result is an array of recesses rather than islands. Each recess has a width of about 2.5 microns, and a depth of about 120 nanometres.

Two-dimensional arrays of indentations were also formed in type (i) single crystal Si (100) samples as described above, but using a Hysitron indenter having a Berkovich tip (3-sided pyramid) to create smaller indentations at loads of up to 5000 μN. As before, the indented samples were then etched for 30 seconds in the KOH solution at 80° C., as described above.

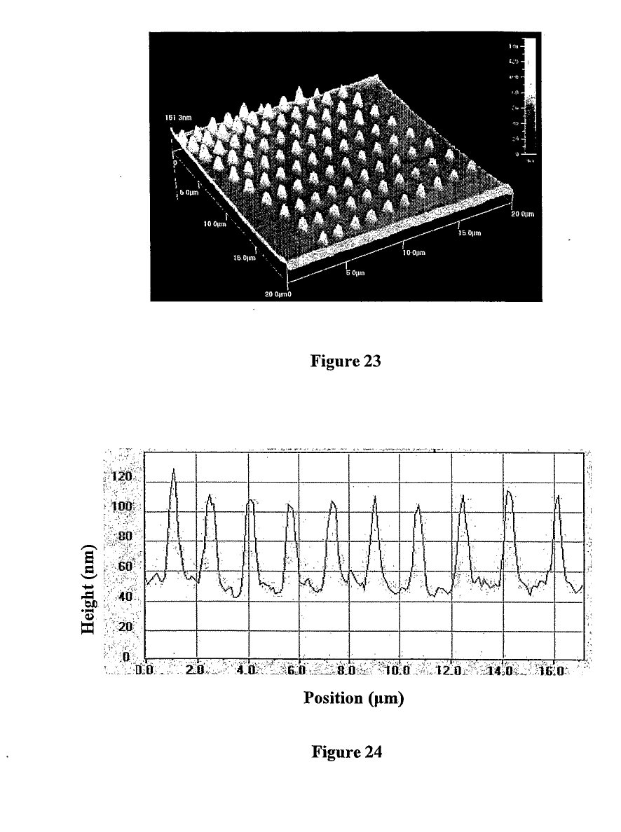

FIG. 23 is an AFM image of a sample indented with fast unloading to create a two-dimensional array of amorphous silicon regions, followed by etching as described above. As expected, the lower etch rate of the resulting amorphous regions produces amorphous silicon islands projecting above the surrounding (100) crystalline Si-I substrate. As shown in the AFM line scan of FIG. 24, each island or mound has a height of approximately 60 nm and a width of about 1 micron.

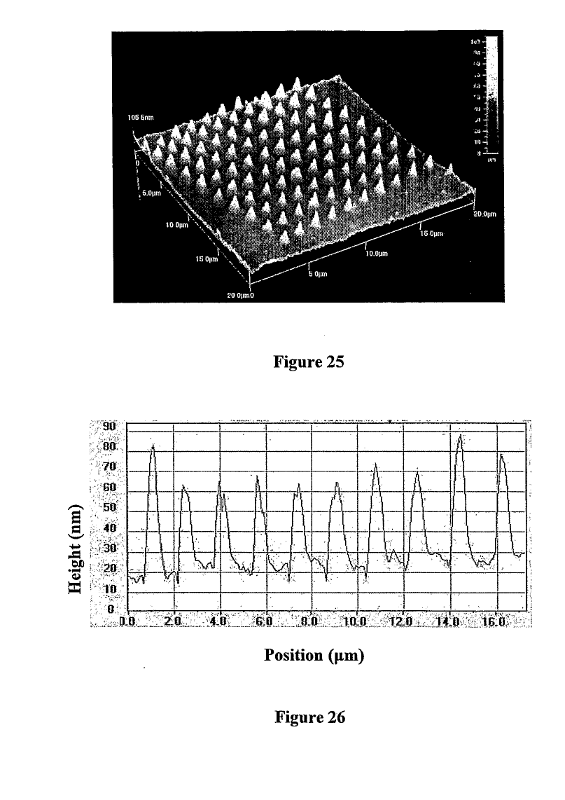

As shown in FIG. 25, when slow unloading is used, the high pressure phases Si-III/Si-XII are formed, and their combined lower etch-rate relative to (100) Si-I again results in the formation of a two-dimensional array of raised islands. As shown in the line scan of FIG. 26, each island has, a height of about 50 nm, and a width of about 1 micron.

The table below summarises the results described above.

| | | | | Etching | | |
|---|---|---|---|---|---|---|
| | | | | result | | |
| | | Experimental | Phase of indented | (island or | Feature | Feature |
| Tip | Substrate | process | region | recess) | height (nm) | width (μm) |
| Spherical | Si-I | fast unload | a-Si | island | 450 | 2.5 |
| | | slow unload | Si-III/Si-XII | island | 800 | 2.5 |
| | | slow unload | Si-III/Si-XII | island | 300 | 3.0 |
| | relaxed | slow unload | Si-I | recess | 120 | 2.5 |
| | a-Si | plus 450° C. | (polycrystalline) | | | |
| | | anneal | | | | |
| Berkovich | Si-I | fast unload | a-Si | island | 60 | 1 |
| | | slow unload | Si-III/Si-XII | island | 50 | 1 |

The indentations described above were formed using standard indenter tips. To form nanoscale transformed regions, an ultra-sharp corner-cube indenter tip of a maximum load to ˜100 μN was used to create transformed regions in Si-I having depths of 10 nm and lateral dimensions of ˜25 nm. In this loading regime the shape and size of each transformed region is limited by the sharpness of the indenter tip. In this case, the tip was a Northstar 90 degrees cube-corner tip having a radius <50 nm, available from Hysitron Inc.

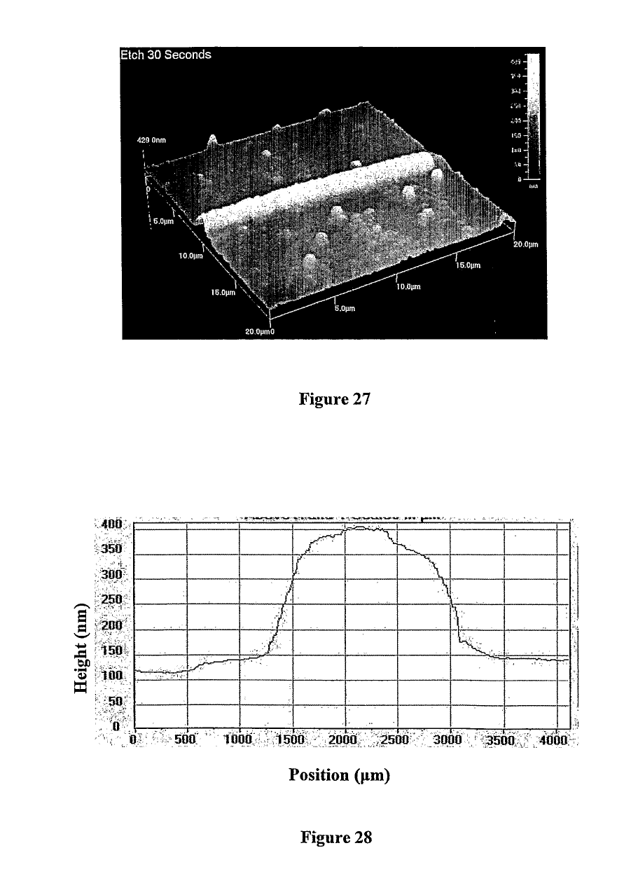

The results described above demonstrate the formation of microscale and nanoscale isolated regions generally corresponding to the dimensions of individual indenter tips. In order to create an extended feature, the indenter was programmed to create a row of overlapping indentations and thereby define a linear extended transformed region or line in a Si-I sample, using loads up to 10,000 μN. As shown in FIG. 27, a 30 second KOH etch of this sample results in the formation of an extended raised linear region of amorphous silicon projecting above the surrounding crystalline (100) Si-I substrate. As shown in FIG. 28, a line scan perpendicular to the longitudinal axis of the amorphous silicon line indicates the line is about 250 nm high and about two microns wide. As shown in FIG. 27, the length of the amorphous line is in excess of 20 microns. It will be apparent that the indenter could be alternatively programmed to produce extended indented regions in almost any shape and thereby form three-dimensional raised features from that shape. If these indentations are formed in a surface layer, such as a thin silicon surface layer of an SOI wafer, the resulting surface features can be released from the underlying substrate by etching the underlying oxide layer to produce one or more three-dimensional objects in the shape (or the complementary shape) of the desired pattern.

Many modifications will be apparent to those skilled in the art without departing from the scope of the present invention as herein described with reference to the accompanying drawings.

1. A pattern transfer process, including:
applying pressure to one or more regions of a surface of a substance to transform a phase of one or more corresponding regions of said substance to a second phase, said pressure being applied in a direction substantially normal to said surface; and
removing said pressure to transform said second phase to at least one third phase;
wherein the respective shapes and relative locations of the regions to which said pressure is applied are selected to transfer a desired pattern to said substance, the transferred pattern being constituted by respective shapes and relative locations of the resulting one or more regions of said at least one third phase.

2. A pattern transfer process, including:
accessing pattern data representing a desired pattern consisting of one or more regions having respective shapes and relative locations;
applying pressure to one or more regions of a substance to transform a phase of one or more corresponding regions of said substance to a second phase, the respective shapes and relative locations of the regions to which said pressure is applied being determined by the pattern data to transfer the desired pattern to said substance; and
removing said pressure to transform said second phase to at least one third phase, the transferred pattern being constituted by the respective shapes and relative locations of the one or more regions of said at least one third phase.

3. The process of claim 2, wherein said regions are transformed to said at least one third phase to change a rate of removal of said regions during a subsequent subtractive process.

4. The process of claim 3, including applying said subtractive process to the substance so that the one or more transformed regions are selectively removed or retained.

5. A pattern transfer process, including:
applying pressure to one or more regions of a substance and removing said pressure to transform a phase of one or more corresponding regions of said substance, the respective shapes and relative locations of the regions to which said pressure is applied being selected to transfer a desired pattern to said substance, the transferred pattern being constituted by respective shapes and relative locations of the one or more transformed regions of said substance; and
applying a subtractive process to the substance, a rate of removal of said substance when subjected to said subtractive process being changed by the transformation so that the one or more transformed regions are selectively removed or retained.

6. The process of claim 5, including heating the transformed regions of said substance to further transform at least one phase of the transformed regions prior to said subtractive process.

7. The process of claim 3, wherein the subtractive process includes a wet or dry etching process, a sputtering process, a plasma process, and/or an ablation process.

8. The process of claim 3, wherein the selective removal or retaining of the one or more transformed regions defines a mask that respectively exposes or masks the one or more transformed regions.

9. The process of claim 3, wherein the subtractive process includes an anisotropic etching process, the selective removal or retaining of the one or more transformed regions defining a etch mask for said anisotropic etching process.

10. The process of claim 9, wherein the process includes masked etching of said substance by said anisotropic etching process to reduce reflection of sunlight from a corresponding surface of a solar cell made from said substance.

11. The process of claim 1, wherein said pressure is applied and removed by stamping said substance with a pressure applicator such that there is no substantial relative lateral movement between said pressure applicator and said substance during said applying and removal of said pressure.

12. The process of claim 1, including:
accessing pattern data representing the desired pattern, the respective shapes and relative locations of the regions to which said pressure is applied being determined on the basis of said pattern data.

13. The process of claim 12, including processing said pattern data to control at least one of the application of pressure to said substance and its removal in order to transfer the desired pattern to said substance.

14. The process of claim 12, wherein said pressure is applied to said substance by a pressure applicator, and the process includes processing said pattern data to determine at least one path for traversal by said pressure applicator while applying said pressure to said substance to enable the transfer of the desired pattern to said substance.

15. The process of claim 12, wherein said pressure is applied to said substance by a pressure applicator, and the process includes processing said pattern data to determine a plurality of locations of said substance, said applying and removal of said pressure including translating said pressure applicator to each of said locations and applying said pressure to said substance at each of said locations and removing said pressure to transfer the desired pattern to said substance, each application and removal of said pressure transferring a corresponding portion of the desired pattern.

16. The process of claim 1, wherein said pressure is applied to said substance by a pressure applicator having one or more projections that apply said pressure to said substance.

17. The process of claim 16, wherein said one or more projections include one or more substantially point-like projections.

18. The process of claim 16, wherein said one or more projections include one or more extended projections.

19. The process of claim 14, wherein said pressure applicator includes one or more of a die, a stylus, and an indenter tip.

20. The process of claim 14, wherein said pressure applicator includes at least one stamp or die having one or more projections for applying said pressure to said substance, the shapes and relative locations of the projections corresponding to the desired pattern, and the process further including forming said one or more projections on the basis of pattern data representing the desired pattern.

21. The process of claim 1, wherein the applying and removal of said pressure includes successively applying pressure to respective regions of said substance and removing said pressure to successively transform corresponding regions of said substance and thereby transfer the desired pattern to said substance, each application and removal of said pressure transferring a corresponding portion of the desired pattern to said substance.

22. The process of claim 21, wherein said pressure is applied to said substance by repeatedly stamping said substance with a pressure applicator, the process including translating said pressure applicator between successive stamping steps to respective locations of said substance to transfer the desired pattern to said substance.

23. The process of claim 21, wherein said applying and removing of said pressure includes successively translating a pressure applicator to a plurality of locations and successively applying pressure to and removing pressure from corresponding regions of said substance to transform a phase of said corresponding regions of said substance and thereby transfer the desired pattern to said substance.

24. The process of claim 21, wherein the applying and removal of said pressure includes rolling a pressure applicator over said substance while applying said pressure in order to successively transform said regions of said substance.

25. The process of claim 21, wherein the successive application of said pressure applicator successively transforms overlapping regions of said substance to form at least one transformed region that includes the overlapping transformed regions.

26. The process of claim 1, wherein said step of applying and removing pressure includes controlling at least one of the applying and removal of said pressure to control the transformation of said one or more regions of said substance.

27. The process of claim 1, wherein said step of applying and removing pressure includes controlling at least one of the applying and removal of said pressure to determine the at least one third phase of the transformed one or more regions of said substance.

28. The process of claim 1, wherein said step of applying and removing pressure includes controlling at least one of the applying and removal of said pressure to determine a shape of the transformed one or more regions of said substance.

29. The process of claim 1, wherein said step of applying and removing pressure includes controlling at least one of the applying and removal of said pressure to determine a lateral extent of the transformed one or more regions of said substance.

30. The process of claim 1, wherein said step of applying and removing pressure includes controlling at least one of the applying and removal of said pressure to determine a thickness of the transformed one or more regions of said substance.

31. The patterning process of claim 1, wherein said step of applying and removing pressure includes controlling a rate of removal of said pressure to control the transformation of said one or more regions of said substance.

32. The process of claim 1, wherein said phase includes a first phase, and said step of applying and removing pressure includes controlling the applying and removing of pressure to determine respective spatial distributions of said second phase and said at least one third phase.

33. The process of claim 27, wherein said controlling of said applying and removing of pressure includes selecting a maximum applied pressure applied to said substance, and controlling one or more rates of removal of said pressure from said substance.

34. The process of claim 33, wherein said controlling includes removing a portion of said pressure at a first removal rate to transform said second phase of one or more first regions to a third phase, and further removing at least a further portion of said pressure at a second removal rate to transform one or more second regions to a fourth phase.

35. The process of claim 1, including further processing the untransformed and transformed regions of said substance to produce a device, at least one of the untransformed and transformed regions providing an active or passive component of said device.

36. The process of claim 35, wherein the one or more transformed regions define at least one component of an electronic, mechanical, and/or optical device, a solar cell or a display device.

37. The process of claim 36, wherein said at least one component includes one or more of the transformed regions of said substance.

38. The process of claim 36, wherein said at least one component includes one or more untransformed regions of said substance.

39. The process of claim 35, wherein the transformation of phase changes at least one property of said substance, the changed at least one property determining a function of at least one component of said device.

40. The process of claim 39, wherein the changed at least one property includes at least one of an electrical property, a chemical property, a thermal property, a mechanical property, and an optical property.

41. The process of claim 1, wherein said pressure is applied to a relaxed amorphous phase of said substance, the one or more regions of said substance being transformed to at least one crystalline phase.

42. The process of claim 1, wherein said pressure is applied to at least one crystalline phase of said substance, the one or more regions of said substance being transformed to an amorphous phase.

43. The process of claim 1, including heating the substance to further transform at least one phase of the transformed regions.

44. The process of claim 43, wherein the transformed regions include Si-III/Si-XII phases, and the process includes heating the substance to further transform the Si-III/Si-XII phases to a Si-I phase.

45. The process of claim 44, wherein said heating also transforms amorphous Si within the Si-III/Si-XII phases to the Si-I phase.

46. The process of claim 1, wherein said substance is a semiconductor.

47. The process of claim 46, wherein said semiconductor is silicon.

48. The process of claim 1, wherein the applying and removal of pressure causes substantially permanent deformation of a surface of said substance to reduce reflection of light from said surface.

49. The process of claim 1, wherein the one or more transformed regions define one or more conducting and/or insulating regions of an electronic device.

50. The process of claim 1, wherein said substance is a semiconductor in the form of a thin film.

51. The process of claim 50, wherein the thin film is attached to a flexible substrate.

52. The process of claim 1, wherein the one or more transformed regions define electrically conducting regions of one or more solar cells.

53. The process of claim 1, to wherein the one or more transformed regions define one or more channels of respective transistors.

54. The process of claim 53, wherein said one or more transistors include one or more thin film transistors of a display device

55. The process of claim 1, wherein substantially the entirety of one surface of said substance is substantially transformed from at least one first phase to at least one second phase.

56. The process of claim 1, wherein the substance is in the form of a layer attached to a substrate, the transformed one or more regions extending substantially through said layer.

57. The process of claim 56, wherein substantially the entirety of said layer of said substance is substantially transformed from at least one first phase to said at least one third phase.

58. The process of claim 1, wherein the one or more regions of said substance to which said pressure is applied are substantially at least one crystalline first phase, and said at least one third phase is substantially an amorphous phase.

59. The process of claim 1, wherein the one or more regions of said substance to which said pressure is applied are substantially an amorphous phase, and said at least one third phase is substantially at least one crystalline phase.

60. The patterning process of claim 1, wherein the one or more regions to which said pressure is applied are substantially a first crystalline phase, and said at least one third phase is substantially at least one second crystalline phase.

61. The patterning process of claim 1, wherein the one or more regions have nanometer-scale dimensions.

62. A pattern transfer system having components for executing the steps of claim 1.

63. A patterned substance formed by executing the steps of claim 1.

64. A device or solar cell having a component formed by executing the steps of claim 1.
